(19) United States
(12) Patent Application Publication
(10) Pub. No.: US 2010/0214354 A1
(43) Pub. Date: Aug. 26, 2010

(54) METHOD OF MANUFACTURING INKJET HEAD AND INKJET RECORDING APPARATUS

(75) Inventor: Hisashi Ohshiba, Ashigarakami-gun (JP)

Correspondence Address: FISH & RICHARDSON P.C., PO BOX 1022, MINNEAPOLIS, MN, 55440-1022, US

(73) Assignee: FUJIFILM Corporation

(21) Appl. No.: 12/711,058

(22) Filed: Feb. 23, 2010

(30) Foreign Application Priority Data
Feb. 24, 2009 (JP) 2009041119

(51) Int. Cl. B41J 2/165; H01L 21/302

(52) U.S. Cl. 347/22; 438/21; 438/700; 438/691; 257/E21.214

(57) ABSTRACT

The method of manufacturing an inkjet head, includes: an opening section forming step of forming, with respect to a SOI substrate having a first silicon layer, a second silicon layer and a first thermal oxide film between the first silicon layer and the second silicon layer, nozzle opening sections passing through the second silicon layer and the first thermal oxide film and reaching the first silicon layer; after the opening section forming step, a first silicon layer removing step of removing the first silicon layer; and after the first silicon layer removal step, a liquid-repellent film forming step of forming a liquid-repellent film on a surface of the first thermal oxide film that has been exposed in the first silicon layer removal step.

### BACKGROUND OF THE INVENTION

1. Field of the Invention

The present invention relates to a method of manufacturing an inkjet head and an inkjet recording apparatus, and more particularly to manufacturing technology which improves wear resistance and liquid resistance of a liquid-repellent film formed on a nozzle surface, and an inkjet recording apparatus employing such technology.

2. Description of the Related Art

An inkjet head used in an inkjet printer, or the like, has a liquid-repellent film formed on the ejection side surface of a nozzle plate (nozzle surface), in order, for instance, to stabilize the flight characteristics of liquid droplets (see Japanese Patent Application Publication Nos. 2003-341070 and 2006-175765). Japanese Patent Application Publication No. 2003-341070 discloses technology for raising the adhesion and durability of a fluoride hydrophobic layer by forming a silicon dioxide (SiO₂) thin film between a base material (resin member) of a nozzle plate and the fluoride hydrophobic layer, and methods such as sputtering, ion beam vapor deposition, ion plating, chemical vapor deposition (CVD) and plasma vapor deposition (P-CVD) are suitable for forming the SiO₂ thin film layer.

However, if a plasma polymer film (silicon oxide film) is used as a undercoating layer for a liquid-repellent film on a nozzle plate, then the plasma polymer film has poor structural density compared to a thermal oxide film, and poor properties in terms of adhesion to the silicon substrate and the liquid-repellent film, chemical resistance, wear resistance, and the like. As a result of this, there is a problem in that it is not possible to achieve an inkjet head which is suitable from the viewpoint of ink resistance and wear resistance.

Japanese Patent Application Publication No. 2006-175765 discloses a method wherein an orifice substrate having nozzle apertures is manufactured by micro electro mechanical system (MEMS) processing of a silicon material, whereupon a silicon oxide layer SiO, (where x<2) is formed on the surface of the orifice substrate, and an ink-repelling film made of a fluoride-based high polymer film is formed over the silicon oxide layer.

According to Japanese Patent Application Publication No. 2006-175765, in a structure in which an orifice substrate, an ink chamber substrate and a diaphragm substrate are bonded into a single body, since it is difficult to apply an ink repelling treatment to the surface of the orifice substrate only, a method has been proposed whereby the orifice substrate and the ink chamber substrate are anodic bonded, whereupon, before bonding to the diaphragm plate, an ink-repelling film is formed over the whole surface of the bonded orifice substrate and ink chamber substrate, and the unwanted region of this ink-repelling film is removed with an oxygen plasma. However, since plasma processing is carried out after bonding the orifice substrate, damage is caused to the main body of the head.

Furthermore, Japanese Patent Application Publication No. 2006-175765 also proposes, as a separate ink film forming method to that described above, a method whereby the orifice substrate and the ink chamber substrate are anodic bonded, whereupon, before bonding the diaphragm plate, a water-soluble masking agent is injected inside the ink chambers to form a masking layer on the side walls of the ink chambers, an ink-repelling film is formed only on the surface of the orifice substrate, and the water-soluble masking agent is then removed. However, this method requires tasks such as bonding a diaphragm plate and adhesion of piezoelectric elements, and the like, after completing the ink-repelling film of the orifice substrate, and there is a possibility of causing damage to the orifice substrate during these processes.

An orifice substrate (nozzle plate) which has a large number of very small orifices (nozzles) is a member which is weak with respect to external forces, and the like, and therefore consideration must be given to handling properties and the sequence of processing steps, so as to avoid causing damage to this member, as far as possible.

### SUMMARY OF THE INVENTION

The present invention has been contrived in view of these circumstances, an object thereof being to provide a method of manufacturing an inkjet head which is capable of improving the wear resistance and liquid resistance of a liquid-repellent film, and to provide a method of manufacturing a target head with good operability while avoiding damage to the nozzle portions, the head main body, and the like, as well as an inkjet recording apparatus using such a head.

In order to attain the aforementioned object, the present invention is directed to a method of manufacturing an inkjet head, comprising: an opening section forming step of forming, with respect to a SOI substrate having a first silicon layer, a second silicon layer and a first thermal oxide film between the first silicon layer and the second silicon layer, nozzle opening sections passing through the second silicon layer and the first thermal oxide film and reaching the first silicon layer; after the opening section forming step, a first silicon layer removing step of removing the first silicon layer; and after the first silicon layer removal step, a liquid-repellent film forming step of forming a liquid-repellent film on a surface of the first thermal oxide film that has been exposed in the first silicon layer removal step.

According to this aspect of the present invention, the thermal oxide film (first thermal oxide film) buried in the SOI substrate is used as an underlying layer of the liquid-repellent film of the nozzle surface, and this thermal oxide film has high structural density and high adhesion with the silicon layer (second silicon layer) and the liquid-repellent film, compared to a plasma polymer film. Thus, the liquid resistance and the wear resistance of the nozzle surface layer constituted of the liquid-repellent film and the thermal oxide film underlying same are improved.

Furthermore, according to this aspect of the present invention, the nozzle opening sections and the first thermal oxide film are covered and protected by the first silicon layer until the first silicon layer is removed, and therefore good handling is obtained. Consequently, by removing the first silicon layer after bonding together the SOI substrate that has completed formation of the nozzle opening sections and the thermal oxide processing, and the like, and the head main body (flow channel structure body) in which flow channel sections and piezoelectric elements, and the like, have been formed, it is possible to manufacture a desired head while protecting the nozzle sections and without damaging the head main body or the piezoelectric elements, or the like.

### BRIEF DESCRIPTION OF THE DRAWINGS

FIGS. 1A to 1J are step diagrams showing a method of manufacturing an inkjet head according to an embodiment of the present invention;

FIG. 2 is a schematic drawing of an inkjet recording apparatus according to an embodiment of the present invention;

FIGS. 3A and 3B are plan view perspective diagrams showing the composition of a print head according to an embodiment of the present invention;

FIG. 4 is a plan view perspective diagram showing the composition of a print head according to another embodiment of the present invention; and

FIG. 5 is a cross-sectional diagram along line 5-5 in FIGS. 3A and 3B.

### DETAILED DESCRIPTION OF THE PREFERRED EMBODIMENTS

### Method of Manufacturing Inkjet Head

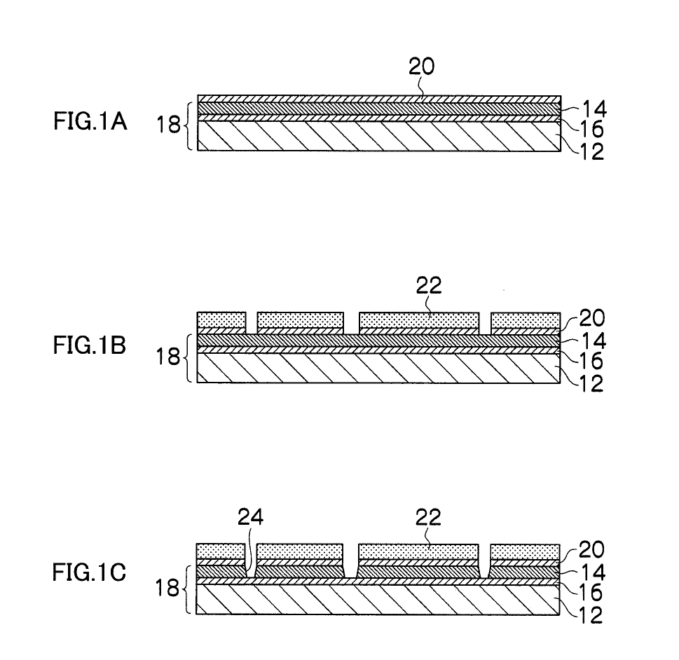

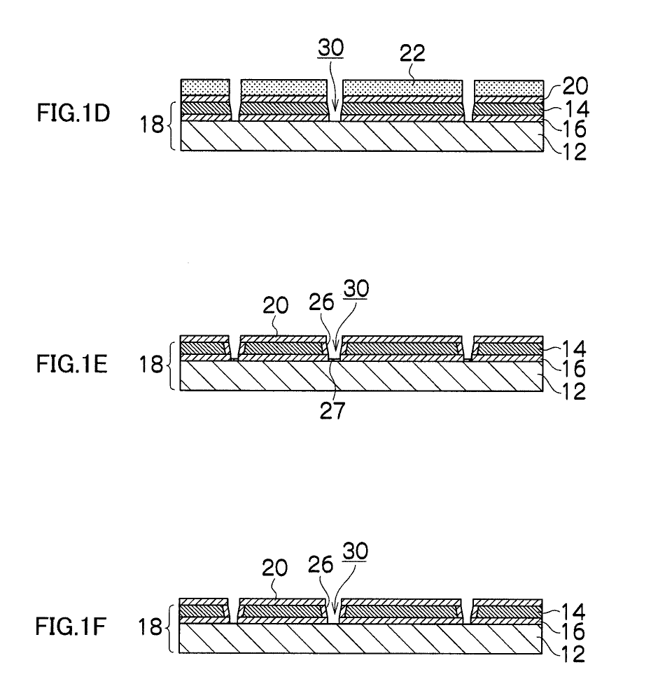

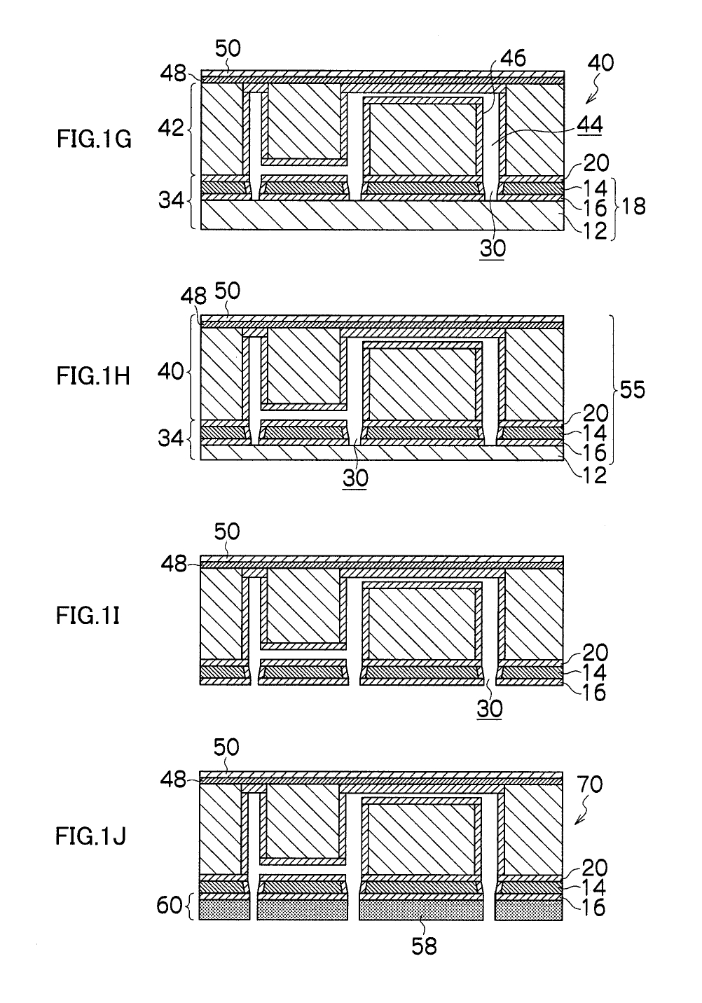

FIGS. 1A to 1J are step diagrams showing a method of manufacturing an inkjet head according to an embodiment of the present invention.

### <Step 1>

Firstly, as shown in FIG. 1A, a substrate (SOI wafer) 18 having an SOI (silicon on insulator) structure in which an insulating layer (SiO₂ layer) of an oxide film 16 is interposed between a first silicon layer 12, which corresponds to a handling layer, and a second silicon layer 14, which corresponds to an active layer, is prepared. The oxide film 16 (this film also referred to as the “buried oxide film”) between the first silicon layer 12 and the second silicon layer 14 is a thermal oxide film formed by thermal oxidation. In the present embodiment, this buried oxide film 16 (which corresponds to the “first thermal oxide film”) is used as an undercoating layer for a liquid-repellent film 58 on the nozzle surface, which is formed at a later stage (see FIG. 1J).

A thermal oxide film 20 is formed on the surface of the second silicon layer 14 of the SOI wafer 18 prepared as described above. The thermal oxide film 20 (which corresponds to the “second thermal oxide film”) functions as a flow channel protection film which protects the flow channel portions, such as the pressure chambers, which are formed at a later stage.

The thicknesses of the silicon layers 12 and 14 shown in FIG. 1A, and the thicknesses of the oxide films 16 and 20 are not limited in particular, and may be designed variously according to the purpose. For example, the thickness of the second silicon layer 14 is in the range of 10 μm to 300 μm, and the thicknesses of the oxide films 16 and 20 are desirably in the range of 0.5 μm to 10 μm.

### <Step 2>

Thereupon, as shown in FIG. 1B, a resist layer 22 is formed on the thermal oxide film 20 with a photoresist, and patterning (nozzle mask patterning) is carried out in accordance with the nozzle aperture forming pattern. The SiO₂ layer of the upper thermal oxide film 20 is wet etched or dry etched, taking this patterned resist layer 22 as a mask, with the nozzle surface facing downward as in FIG. 1B. In this etching step, the second silicon layer 14 acts as a stopper (etching stop layer). A buffered hydrofluoric acid (HF) is suitable as the etchant for the wet etching.

### <Step 3>

Then, as shown in FIG. 1C, anisotropic wet etching of the upper silicon layer (second silicon layer 14) is carried out with the nozzle surface side facing downward. In this etching process, the buried oxide film 16 acts as a stopper. Aqueous solution of potassium hydroxide (KOH), for example, is suitable as the etchant used here. Thereby, nozzle aperture portions having a narrow-ended (tapered) shape in which the cross-sectional area of the flow channel gradually becomes smaller toward the lower side are formed, as denoted with reference numeral 24.

### <Step 4>

Then, as shown in FIG. 1D, anisotropic dry etching of the buried oxide film 16 is performed in the portions corresponding to the nozzle apertures, with the nozzle surface facing downward. In this etching process, the lower silicon layer (first silicon layer 12) acts as a stopper. Thereby, nozzle opening sections 30 are formed, which pass through the thermal oxide film 20, the second silicon layer 14 and the buried oxide film 16, and reach the first silicon layer 12.

### <Step 5>

Then, as shown in FIG. 1E, the resist layer 22 is removed, and thermal oxide films 26 and 27 are formed by a thermal oxide method on the exposed surfaces of the silicon layers 12 and 14. Thereby, the thermal oxide film 26 serving as a flow channel protection film (which corresponds to a “third thermal oxide film”) is formed on the inner surface of the nozzle opening portions 30. The film thicknesses of the thermal oxide films 26 and 27 are desirably 0.5 μm to 1 μm. In order to clarify the drawings, the thicknesses of the silicon layers 12 and 14 and the oxide film layers 16, 20, 26 and 27 are depicted with suitable adjustments, and the drawings do not accurately reflect the actual ratio of the film thicknesses.

### <Step 6>

Then, as shown in FIG. 1F, the thermal oxide film 27 on the first silicon layer 12 formed in the step 5 is removed by anisotropic dry etching. In this etching step, the lower silicon layer (first silicon layer 12) acts as a stopper. Since this step uses anisotropic dry etching, the thermal oxide film 26 of the inner circumferential surfaces of the nozzles is left.

### <Step 7>

Then, as shown in FIG. 1G, a wafer (referred to as the “nozzle wafer”) 34 of the nozzle plate portion obtained by the above-described steps 1 through 6, and a wafer (referred to as a “base wafer”) 42 of a flow channel structure body 40 fabricated by a separate step, are bonded together.

Flow channels 44 (including a pressure chamber, nozzle connection channel, common flow channel, and the like), which connect to the nozzle opening sections 30, have been formed in the base wafer 42. Moreover, a thermal oxide film (SiO₂ film) 46 serving as a flow channel protection film has been formed over the whole surface of the interior of the flow channels 44. Furthermore, a diaphragm 48 and a piezoelectric body film 50 have been bonded to the base wafer 42 in the present embodiment. Although not shown in the drawings, an electrode layer which corresponds to a common electrode has been formed on the interface between the diaphragm 48 and the piezoelectric body film 50, and individual electrodes corresponding to the upper electrodes of the piezoelectric elements corresponding to the respective nozzles have been patterned on the upper surface of the layer of the piezoelectric body film 50.

As described above, before bonding the nozzle wafer 34 and the base wafer 42, the base wafer 42 that can be bonded to the nozzle wafer 34 has been manufactured. More specifically, the base wafer 42 in which the flow channel structure body 40 is formed has been prepared separately from the nozzle wafer 34, by a manufacturing process for forming the internal flow channels and forming the piezoelectric elements.

### <Step 8>

Then, as shown in FIG. 1H, the first silicon layer 12 of the head structure body 55 bonded in the step 7 is ground to reduce the thickness of the first silicon layer 12. For instance, the grinding is carried out in such a manner that the first silicon layer 12 has a thickness of approximately 0.1 μm to 300 μm left.

### <Step 9>

Thereupon, as shown in FIG. 1I, the first silicon layer 12 left after the step 8 is dry etched and the first silicon layer 12 is completely removed. In this etching process, the buried oxide film 16 acts as a stopper.

Since the process speed of the grinding in the step 8 is faster than the etching in the step 9, the majority of the first silicon layer 12 is removed by the grinding in step 8, and the small remaining portion is removed by the etching in the step 9, whereby it is possible to achieve both significant reduction in the processing time and high processing accuracy, and there is little damage to the nozzle sections.

### <Step 10>

Then, as shown in FIG. 1J, the liquid-repellent film 58 is formed on the surface (the lower surface in FIG. 1J) of the once-buried oxide film 16, which has been exposed in the step 9. As a method for forming the liquid-repellent film 58, it is possible to employ, for example, a method which applies a fluoride liquid-repellent agent by spin coating, roller coating, dipping, screen printing, spray coating, or the like, or a method which deposits a film by vacuum vapor deposition or a CVD apparatus.

Thus, a nozzle surface layer 60 constituted of laminated layers of the liquid-repellent film 58 and the thermal oxide film (once-buried oxide film) 16 is formed. The thermal oxide film (once-buried oxide film) 16 is strongly bonded chemically to the liquid-repellent film 58, thereby improving adhesion. By means of the steps 1 to 10 described above, the inkjet head 70 is completed.

According to the method of manufacture according to the present embodiment, since the under layer of the liquid-repellent film 58 of the nozzle surface is formed by the buried oxide film (thermal oxide film) 16 of the SOI wafer 18, then the structural density is improved in comparison with a plasma polymer film in the related art, or the like, and furthermore, the adhesion with the underlying silicon layer (the second silicon layer) 14 and the liquid-repellent film 58 is improved, and it is possible to the improve ink resistance and wear resistance of the nozzle surface layer 60.

### Modified Embodiment 1

It is possible to omit the steps in FIGS. 1E and 1F for forming the thermal oxide film 26 inside the nozzles.

### Modified embodiment 2

It is possible to form a separate protective film, instead of the thermal oxide film 46 for protecting the flow channels formed inside the flow channels 44 of the flow channel structure body 40. Furthermore, it is also possible to adopt a mode which omits the thermal oxide film 20 described with reference to FIG. 1A.

### Modified embodiment 3

In FIGS. 1G to 1J, the case has been shown in which the piezoelectric elements are bonded to the flow channel structure body 40, but the present invention is not limited to this, and it is also possible to adopt modes such as a flow channel structure body in which piezoelectric elements are not bonded or a flow channel structure body to which a diaphragm is not bonded either, and a diaphragm bonding step, a piezoelectric film bonding step, an individual electrode forming step, and the like, may be carried out either before or after the step of bonding the flow channel structure to the nozzle wafer.

### Modified embodiment 4

Furthermore, the devices for generating pressure for ejection (ejection energy) in order to eject liquid droplets from the nozzles in the inkjet head are not limited to the piezoelectric elements, and it is possible to employ various pressure generating elements (energy generation elements), such as actuators operated by heaters (heating elements) based on a thermal method, or actuators using another ejection method. Energy generating elements which correspond to the ejection method of the head are provided in the flow channel structure body.

The step of forming the energy generating elements in the flow channel structure body can be carried out before bonding the flow channel structure body to the nozzle wafer, and can also be carried out after bonding the flow channel structure body to the nozzle wafer.

By forming the energy generating elements in the flow channel structure body before bonding the nozzle wafer and the flow channel structure body, it is possible to form the nozzle sections without damaging the energy generating elements. Furthermore, it is also possible to carry out drive tests of the energy generating elements, and the like, in the independent unit of the structure body in which the energy generating elements are provided.

### Embodiment of Composition of Inkjet Recording Apparatus

Next, an embodiment of an inkjet recording apparatus using the inkjet head manufactured by the method of manufacture described above is explained.

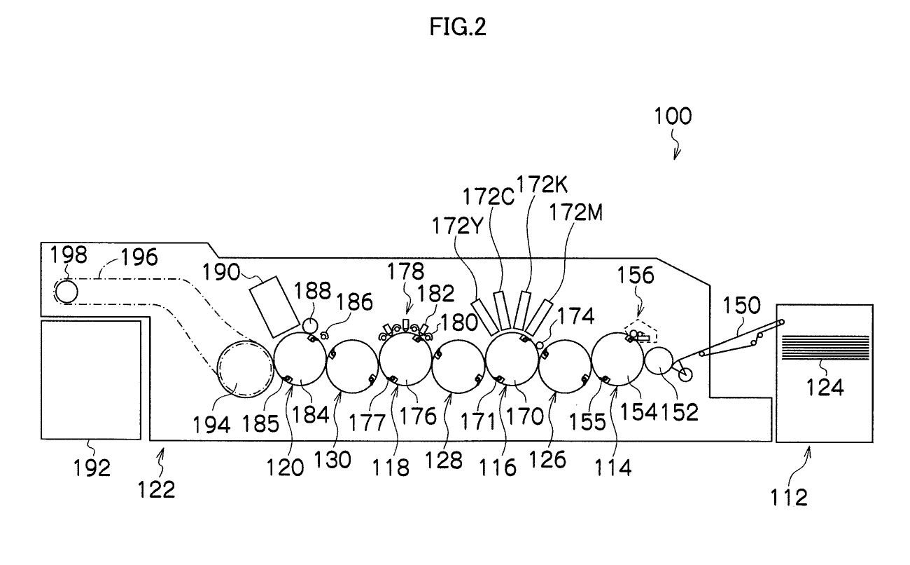

FIG. 2 is a structural diagram illustrating the configuration of an inkjet recording apparatus 100 according to an embodiment of the present invention. The inkjet recording apparatus 100 is an inkjet recording apparatus of a so-called pressure-drum direct image-formation system which records a desired color image on a recording medium (hereinafter also referred to as “paper”) 124 held on a pressure drum (an image formation drum 170) of an image formation unit 116 by ejecting and depositing droplets of ink of a plurality of colors from inkjet heads 172M, 172K, 172C and 172Y onto the recording medium 124. More specifically, the inkjet recording apparatus 100 is a recording apparatus of a on-demand type which adapts a two-liquids reaction (aggregation in the present embodiment) system in which treatment liquid (aggregation treatment liquid in the present embodiment) is applied onto the recording medium 124 prior to the deposition of the ink, so that the deposited ink reacts with the treatment liquid to form images on the recording medium 124.

The inkjet recording apparatus 100 includes a paper feed unit 112, a treatment liquid application unit 114, the image formation unit 116, a drying unit 118, a fixing unit 120, and a discharge unit 122 as the main components.

### <Paper Feed Unit>

The paper feed unit 112 feeds the recording medium 124 to the treatment liquid application unit 114. The recording medium 124 (paper sheets) is stacked in the paper feed unit 112. The paper feed unit 112 is provided with a paper feed tray 150, and the recording medium 124 is fed, sheet by sheet, from the paper feed tray 150 to the treatment liquid application unit 114.

In the inkjet recording apparatus 100 according to the present embodiment, it is possible to use recording media 124 of different types and various sizes as the recording medium 124. A mode can be adopted in which the paper feed unit 112 is provided with a plurality of paper trays (not illustrated) in which recording media of different types are respectively sorted and stacked, and the paper that is fed to the paper feed tray 150 from the paper trays is automatically switched, and a mode can also be adopted in which an operator selects or exchanges the paper tray in accordance with requirements. In the present embodiment, cut sheets of paper are used as the recording media 124, but it is also possible to cut paper to a required size from a continuous roll of paper and then supply this paper.

### <Treatment Liquid Application Unit>

The treatment liquid application unit 114 is a mechanism that applies the treatment liquid to the recording surface of the recording medium 124. The treatment liquid includes a coloring material aggregating agent that causes the aggregation of a coloring material (pigment in the present embodiment) included in the ink applied in the image formation unit 116, and the separation of the coloring material and a solvent in the ink is enhanced when the treatment liquid is brought into contact with the ink.

As shown in FIG. 2, the treatment liquid application unit 124 includes a paper transfer drum 152, a treatment liquid drum 154, and a treatment liquid application device 156. The treatment liquid drum 154 is a drum that holds and rotationally conveys the recording medium 124. The treatment liquid drum 154 is provided on the outer circumferential surface thereof with a hook-shaped holding device (gripper) 155, which holds the leading end of the recording medium 124 by gripping the recording medium 124 between the hook of the gripper 155 and the circumferential surface of the treatment liquid drum 154. The treatment liquid drum 154 may be provided with suction apertures on the outer circumferential surface thereof and connected to a suction device that performs suction from the suction apertures. As a result, the recording medium 124 can be tightly held on the outer circumferential surface of the treatment liquid drum 154.

The treatment liquid application device 156 is provided on the outside of the treatment liquid drum 154 opposite the outer circumferential surface thereof. The treatment liquid application device 156 includes: a treatment liquid container, in which the treatment liquid to be applied is held; an anilox roller, a part of which is immersed in the treatment liquid held in the treatment liquid container; and a rubber roller, which is pressed against the anilox roller and the recording medium 124 that is held by the treatment liquid drum 154, so as to transfer the treatment liquid metered by the anilox roller to the recording medium 124. The treatment liquid application device 156 can apply the treatment liquid onto the recording medium 124 while metering.

In the present embodiment, the application system using the roller is used; however, the present invention is not limited to this, and it is possible to employ a spraying method, an inkjet method, or other methods of various types.

The recording medium 124 that has been applied with the treatment liquid in the treatment liquid application unit 114 is transferred from the treatment liquid drum 154 through the intermediate conveyance unit 126 to the image formation drum 170 of the image formation unit 116.

### <Image Formation Unit>

The image formation unit 116 includes the image formation drum 170, a paper pressing roller 174 and the inkjet heads 172M, 172K, 172C and 172Y. Similar to the treatment liquid drum 154, the image formation drum 170 is provided on the outer circumferential surface thereof with a hook-shaped holding device (gripper) 171. The recording medium 124 held on the image formation drum 170 is conveyed in a state where the recording surface thereof faces outward, and inks are deposited on the recording surface by the inkjet heads 172M, 172K, 172C and 172Y.

The inkjet heads 172M, 172K, 172C and 172Y are recording heads (inkjet heads) of the inkjet system of the full line type that have a length corresponding to the maximum width of the image formation region in the recording medium 124. A nozzle row is formed on the ink ejection surface of the inkjet head. The nozzle row has a plurality of nozzles arranged therein for discharging ink over the entire width of the image recording region. Each of the inkjet heads 172M, 172K, 172C and 172Y is fixedly disposed so as to extend in the direction perpendicular to the conveyance direction (rotation direction of the image formation drum 170) of the recording medium 124.

Droplets of corresponding colored inks are ejected from the inkjet heads 172M, 172K, 172C and 172Y toward the recording surface of the recording medium 124 held tightly on the image formation drum 170, and thereby the ink comes into contact with the treatment liquid that has been heretofore applied on the recording surface by the treatment liquid application unit 114, the coloring material (pigment) dispersed in the ink is aggregated, and a coloring material aggregate is formed. Thus, the coloring material flow on the recording medium 124 is prevented, and an image is formed on the recording surface of the recording medium 124.

In the present embodiment, the CMYK standard color (four colors) configuration is described, but combinations of ink colors and numbers of colors are not limited to that of the present embodiment, and if necessary, light inks, dark inks, and special color inks may be added. For example, a configuration is possible in which inkjet heads are added that eject light inks such as light cyan and light magenta. The arrangement order of color heads is also not limited.

The recording medium 124 on which the image has been formed in the image formation unit 116 is transferred from the image formation drum 170 through an intermediate conveyance unit 128 to a drying drum 176 of the drying unit 118.

### <Drying Unit>

The drying unit 118 dries water included in the solvent separated by the coloring material aggregation action. As shown in FIG. 2, the drying unit includes the drying drum 176 and a solvent dryer 178.

Similar to the treatment liquid drum 154, the drying drum 176 is provided on the outer circumferential surface thereof with a hook-shaped holding device (gripper) 177, which can hold the recording medium 124 by gripping the leading end portion of the recording medium 124.

The solvent dryer 178 is disposed in a position facing the outer circumferential surface of the drying drum 176, and includes a plurality of halogen heaters 180, and a plurality of warm-air blow-out nozzles 182, each of which is arranged between adjacent two of the halogen heaters 180.

Each of the warm-air blow-out nozzles 182 is controlled to blow warm air at appropriate temperature at an appropriate blowing rate toward the recording medium 124, and each of the halogen heaters 180 is controlled to appropriate temperature, and it is thereby possible to implement various drying conditions.

The surface temperature of the drying drum 176 is set to 50° C. or above. By heating from the rear surface of the recording medium 124, drying is promoted and breaking of the image during fixing can be prevented. There are no particular restrictions on the upper limit of the surface temperature of the drying drum 176, but from the viewpoint of the safety of maintenance operations such as cleaning the ink adhering to the surface of the drying drum 176 (namely, preventing burns due to high temperature), desirably, the surface temperature of the drying drum 176 is not higher than 75° C. (and more desirably, not higher than 60° C.).

By holding the recording medium 124 in such a manner that the recording surface thereof is facing outward on the outer circumferential surface of the drying drum 176 (in other words, in a state where the recording surface of the recording medium 124 is curved in a convex shape), and drying while conveying the recording medium in rotation, it is possible to prevent the occurrence of wrinkles or floating up of the recording medium 124, and therefore drying non-uniformities caused by these phenomena can be prevented reliably.

The recording medium 124 which has been subjected to the drying treatment in the drying unit 118 is transferred from the drying drum 176 through an intermediate conveyance unit 130 to a fixing drum 184 of the fixing unit 120.

### <Fixing Unit>

The fixing unit 120 includes a fixing drum 184, a halogen heater 186, a fixing roller 188, and an inline sensor 190. Similar to the treatment liquid drum 154, the fixing drum 184 is provided on the outer circumferential surface thereof with a hook-shaped holding device (gripper) 185, which can hold the recording medium 124 by gripping the leading end portion of the recording medium 124. The recording medium 124 is conveyed by rotation of the fixing drum 184 in a state where the recording surface thereof faces outward, and the preheating by the halogen heater 186, the fixing treatment by the fixing roller 188 and the inspection by the inline sensor 190 are performed with respect to the recording surface.

The halogen heater 186 is controlled to a prescribed temperature (for example, 180° C.), by which the preheating is performed with respect to the recording medium 124.

The fixing roller 188 is a roller member which applies pressure and heat to the dried ink to melt and fix the self-dispersible polymer particles in the ink so as to transform the ink into the film. More specifically, the fixing roller 188 is arranged so as to be pressed against the fixing drum 184, and a nip roller is configured between the fixing roller 188 and the fixing drum 184. As a result, the recording medium 124 is squeezed between the fixing roller 188 and the fixing drum 184, nipped under a prescribed nip pressure (for example, 0.15 MPa), and subjected to fixing treatment.

Further, the fixing roller 188 is configured by a heating roller in which a halogen lamp is incorporated in a metal pipe, for example made from aluminum, having good thermal conductivity and the rollers are controlled to a prescribed temperature (for example 60° C. to 80° C.). Where the recording medium 124 is heated with the heating roller, thermal energy not lower than a Tg temperature (glass transition temperature) of a latex included in the ink is applied and latex particles are melted. As a result, fixing is performed by penetration into the projections-recessions of the recording medium 124, the projections-recessions of the image surface are leveled out, and gloss is obtained.

The fixing unit 120 in the embodiment shown in FIG. 2 is provided with the single fixing roller 188; however, it is possible that the fixing roller 188 has a configuration provided with a plurality of steps, depending on the thickness of image layer and Tg characteristic of latex particles.

On the other hand, the inline sensor 190 is a measuring device which measures the check pattern, moisture amount, surface temperature, gloss, and the like of the image fixed to the recording medium 124. A CCD sensor or the like can be used for the inline sensor 190.

With the fixing unit 120 of the above-described configuration, the latex particles located within a thin image layer formed in the drying unit 118 are melted by application of pressure and heat by the fixing roller 188. Thus, the latex particles can be reliably fixed to the recording medium 124. The surface temperature of the fixing drum 184 is set to 50° C. or above. Drying is promoted by heating the recording medium 124 held on the outer circumferential surface of the fixing drum 184 from the rear surface, and therefore breaking of the image during fixing can be prevented, and furthermore, the strength of the image can be increased by the effects of the increased temperature of the image.

### <Discharge Unit>

As shown in FIG. 2, the discharge unit 122 is provided after the fixing unit 20. The discharge unit 122 includes a discharge tray 192, and a transfer drum 194, a conveying belt 196, and a tension roller 198 are provided between the discharge tray 192 and the fixing drum 184 of the fixing unit 120 so as to face the discharge tray 192 and the fixing drum 184. The recording medium 124 is fed by the transfer drum 194 onto the conveying belt 196 and discharged onto the discharge tray 192.

### <Other Units>

Although not shown in the drawings, the inkjet recording apparatus 100 according to the present invention also includes, in addition to the above-described units: an ink storing and loading unit for supplying the inks to the inkjet heads 172M, 172K, 172C and 172Y; a treatment liquid supply unit for supplying the treatment liquid to the treatment liquid application unit 114; a head maintenance unit for cleaning the inkjet heads 172M, 172K, 172C and 172Y (e.g., wiping of the nozzle surface, purging, and suction for the nozzles); position determination sensors for determining the position of the recording medium 124 in the medium conveyance path; and temperature sensors for measuring temperature in the respective parts of the inkjet recording apparatus 100.

### <Structure of Inkjet Heads>

Next, the structure of the inkjet heads is described. The inkjet heads 172M, 172K, 172C and 172Y for the respective colored inks have the same structure, and a reference numeral 250 is hereinafter designated to any of the inkjet heads.

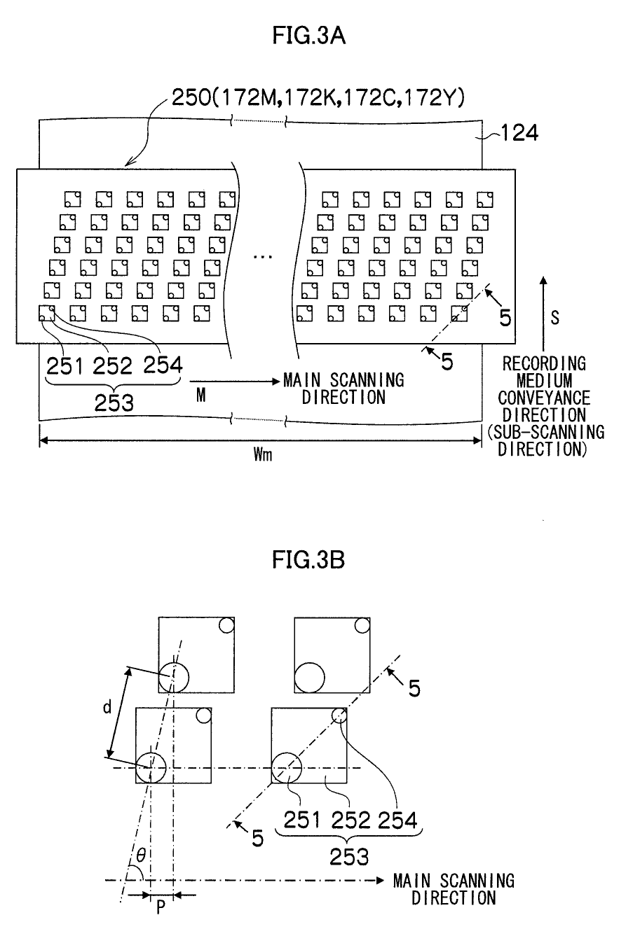

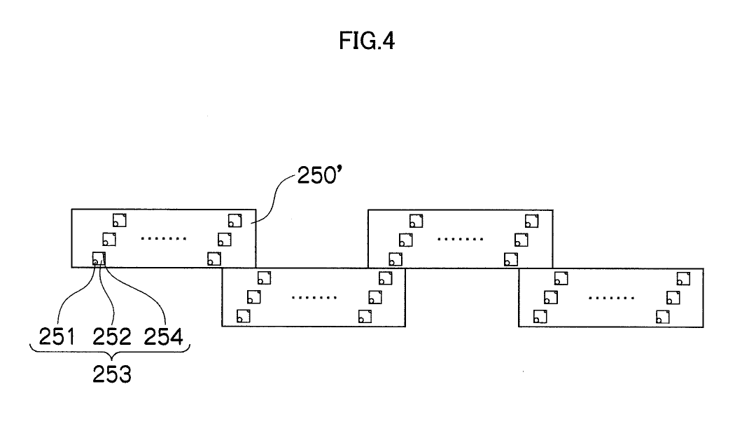

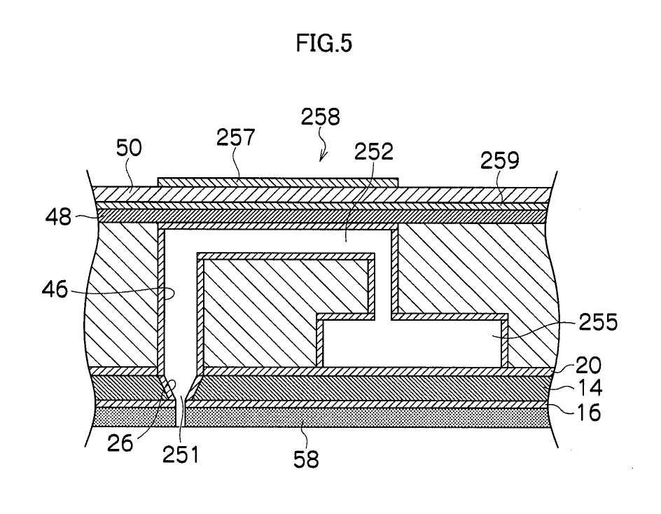

FIG. 3A is a perspective plan view showing an embodiment of the configuration of the head 250, and FIG. 3B is an enlarged view of a portion thereof FIG. 4 is a perspective plan view showing another embodiment of the configuration of the head 250. FIG. 5 is a cross-sectional view taken along the line 5-5 in FIGS. 3A and 3B, showing the inner structure of the droplet ejection unit for one channel (an ink chamber unit corresponding to one nozzle 251), which is an element of recording device.

As shown in FIGS. 3A and 3B, the head 250 according to the present embodiment has a structure in which a plurality of ink chamber units (droplet ejection units) 253, each having a nozzle 251 forming an ink ejection aperture, a pressure chamber 252 corresponding to the nozzle 251, and the like, are disposed two-dimensionally in the form of a matrix, and hence the effective nozzle interval (the projected nozzle pitch) as projected in the lengthwise direction of the head 250 (the direction perpendicular to the conveyance direction of the recording medium 124) is reduced and high nozzle density is achieved.

The mode of forming one or more nozzle rows through a length corresponding to the entire width Wm of the recording medium 124 in the main scanning direction (represented with an arrow M) substantially perpendicular to the conveyance direction of the recording medium 124 (represented with an arrow S, the sub-scanning direction) is not limited to the embodiment described above. For example, instead of the configuration in FIG. 3A, as shown in FIG. 4, a line head having nozzle rows of a length corresponding to the entire width of the recording medium 124 can be formed by arranging and combining, in a staggered matrix, short head blocks 250′ having a plurality of nozzles 251 arrayed in a two-dimensional fashion.

The planar shape of the pressure chamber 252 provided for each nozzle 251 is substantially a square (see FIGS. 3A and 3B), and an ink outlet to the nozzle 251 and an ink inlet (supply port) 254 are disposed in both corners on a diagonal line of the square. The shape of the pressure chamber 252 is not limited to that of the present embodiment, and a variety of planar shapes, for example, a polygon such as a rectangle (rhomb, rectangle, etc.), a pentagon and a heptagon, a circle, and an ellipse can be employed.

Each pressure chamber 252 is connected to a common channel 255 through the supply port 254. The common channel 255 is connected to an ink tank (not shown), which is a base tank for supplying ink, and the ink supplied from the ink tank is delivered through the common flow channel 255 to the pressure chambers 252.

A piezoelectric element 258 provided with an individual electrode 257 is bonded to the diaphragm 48, which forms a face (the upper face in FIG. 5) of the pressure chamber 252. The diaphragm 48 in the present embodiment is formed of silicon (Si) having a conductive layer of nickel (Ni), which acts as a common electrode 259, and also serves as the common electrode for the actuators (here, the piezoelectric devices) 258 arranged correspondingly to the respective pressure chambers 252. A mode is also possible in which the diaphragm is formed by a non-conductive material, such as resin, and in this case, a common electrode layer made of a conductive material, such as metal, is formed on the surface of the diaphragm member. Moreover, it is possible that the diaphragm also serving as the common electrode is made of metal (a conductive material) such as stainless steel (SUS).

When a drive voltage is applied to the individual electrode 257, the piezoelectric element 258 is deformed, the volume of the pressure chamber 252 is thereby changed, and the ink is ejected from the nozzle 251 by the variation in pressure that follows the variation in volume. When the piezoelectric element 258 returns to the original state after the ink has been ejected, the pressure chamber 252 is refilled with new ink from the common channel 255 through the supply port 254.

As shown in FIG. 3B, the high-density nozzle head according to the present embodiment is achieved by arranging the plurality of ink chamber units 253 having the above-described structure in a lattice fashion based on a fixed arrangement pattern, in a row direction which coincides with the main scanning direction, and a column direction which is inclined at a fixed angle of θ with respect to the main scanning direction, rather than being perpendicular to the main scanning direction. More specifically, by adopting a structure in which the ink chamber units 253 are arranged at a uniform pitch d in line with a direction forming the angle of θ with respect to the main scanning direction, the pitch P of the nozzles projected so as to align in the main scanning direction is d×cosθ, and hence the nozzles 251 can be regarded to be equivalent to those arranged linearly at a fixed pitch P along the main scanning direction.

The present embodiment applies the piezoelectric elements 258 as ejection power generation devices to eject the ink from the nozzles 251 arranged in the head 250; however, instead, a thermal system that has heaters within the pressure chambers 252 to eject the ink using the pressure resulting from film boiling by the heat of the heaters can be applied.

In implementing the present invention, the mode of arrangement of the nozzles 251 in the head 250 is not limited in particular, and various difference nozzle arrangement structures can be employed. For example, instead of a matrix arrangement as described in FIGS. 3A and 3B, it is also possible to use a single linear arrangement, a V-shaped nozzle arrangement, or an undulating nozzle arrangement, such as zigzag configuration (W-shape arrangement), which repeats units of V-shaped nozzle arrangements.

According to the composition in which the full line heads having the nozzle rows covering the full width of the image forming region of the recording medium 124 are provided respectively for the colors of ink as described above, it is possible to record an image on the image forming region of the recording medium 124 by conveying the recording medium 124 with the image formation drum 170 at a specific speed while performing just one operation of moving the recording medium 124 and the inkjet heads 172M, 172K, 172C and 172Y relatively with respect to each other in the conveyance direction (the sub-scanning direction) (in other words, by one sub-scanning action). This single-pass type image formation with such the full line type (page-wide) heads can achieve a higher printing speed compared to a case of a multi-pass type image formation with a serial (shuttle) type of head which moves back and forth reciprocally in the direction (the main scanning direction) perpendicular to the conveyance direction of the recording medium (the sub-scanning direction), and hence it is possible to improve the print productivity.

The scope of application of the present invention is not limited to a printing system based on the line type of head, and it is also possible to adopt a serial system where a short head that is shorter than the breadthways dimension of the recording medium 124 is moved in the breadthways direction (main scanning direction) of the recording medium 124, thereby performing printing in the breadthways direction, and when one printing action in the breadthways direction has been completed, the recording medium 124 is moved through a prescribed amount in the sub-scanning direction perpendicular to the breadthways direction, printing in the breadthways direction of the recording medium 124 is carried out in the next printing region, and by repeating this sequence, printing is performed over the whole surface of the printing region of the recording medium 124.

### <Ink>

The ink used in the present embodiment is aqueous pigment ink that contains the following materials insoluble to the solvent (water): pigment particles as the coloring material, and polymer particles.

It is desirable that the concentration of the solvent-insoluble materials in the ink is not less than 1 wt % and not more than 20 wt %, taking account of the fact that the viscosity of the ink suitable for ejection is 20 mPa·s or lower. It is more desirable that the concentration of the pigment in the ink is not less than 4 wt %, in order to obtain good optical density in the image.

It is desirable that the surface tension of the ink is not less than 20 mN/m and not more than 40 mN/m, taking account of ejection stability in the ink ejection head.

The coloring material in the ink may be pigment or a combination of pigment and dye. From the viewpoint of the aggregating characteristics when the ink comes into contact with the treatment liquid, a dispersed pigment in the ink is desirable for more effective aggregation. Desirable pigments include: a pigment dispersed by a dispersant, a self-dispersing pigment, a pigment in which the pigment particle is coated with a resin (hereinafter referred to as “microcapsule pigment”), and a polymer grafted pigment. Moreover, from the viewpoint of the aggregating characteristics of the coloring material, it is more desirable that the coloring material is modified with a carboxyl group having a low degree of disassociation.

It is desirable in the present embodiment that the colored ink liquid contains polymer particles that do not contain any colorant, as a component for reacting with the treatment liquid. The polymer particles can improve the image quality by strengthening the ink viscosity raising action and the aggregating action through reaction with the treatment liquid. In particular, a highly stable ink can be obtained by adding anionic polymer particles to the ink.

By using the ink containing the polymer particles that produce the viscosity raising action and the aggregating action through reaction with the treatment liquid, it is possible to increase the quality of the image, and at the same time, depending on the type of polymer particles, the polymer particles may form a film on the recording medium, and therefore beneficial effects can be obtained in improving the wear resistance and the waterproofing characteristics of the image.

The method of dispersing the polymer particles in the ink is not limited to adding an emulsion of the polymer particles to the ink, and the resin may also be dissolved, or included in the form of a colloidal dispersion, in the ink.

The polymer particles may be dispersed by using an emulsifier, or the polymer particles may be dispersed without using any emulsifier. For the emulsifier, a surface active agent of low molecular weight is generally used, and it is also possible to use a surface active agent of high molecular weight. It is also desirable to use a capsule type of polymer particles having an outer shell composed of acrylic acid, methacrylic acid, or the like (core-shell type of polymer particles in which the composition is different between the core portion and the outer shell portion).

Examples of the resin component added as the resin particles to the ink include: an acrylic resin, a vinyl acetate resin, a styrene-butadiene resin, a vinyl chloride resin, an acryl-styrene resin, a butadiene resin, and a styrene resin.

In order to make the polymer particles have high speed aggregation characteristics, it is desirable that the polymer particles contain a carboxylic acid group having a low degree of disassociation. Since the carboxylic acid group is readily affected by change of pH, then the polymer particles containing the carboxylic acid group easily change the state of the dispersion and have high aggregation characteristics.

The change in the dispersion state of the polymer particles caused by change in the pH can be adjusted by means of the component ratio of the polymer particle having a carboxylic acid group, such as ester acrylate, or the like, and it can also be adjusted by means of an anionic surfactant which is used as a dispersant.

Desirably, the resin constituting the polymer particles is a polymer that has both of a hydrophilic part and a hydrophobic part. By incorporating a hydrophobic part, the hydrophobic part is oriented toward to the inner side of the polymer particle, and the hydrophilic part is oriented efficiently toward the outer side, thereby having the effect of further increasing the change in the dispersion state caused by change in the pH of the liquid. Therefore, aggregation can be performed more efficiently.

Moreover, two or more types of polymer particles may be used in combination in the ink.

Examples of the pH adjuster added to the ink in the present embodiment include an organic base and an inorganic alkali base, as a neutralizing agent. In order to improve storage stability of the ink for inkjet recording, the pH adjuster is desirably added in such a manner that the ink for inkjet recording has the pH of 6 through 10.

It is desirable in the present embodiment that the ink contains a water-soluble organic solvent, from the viewpoint of preventing nozzle blockages in the ejection head due to drying. Examples of the water-soluble organic solvent include a wetting agent and a penetrating agent.

Examples of the water-soluble organic solvent in the ink are: polyhydric alcohols, polyhydric alcohol derivatives, nitrous solvents, monohydric alcohols, and sulfurous solvents.

Apart from the foregoing, according to requirements, it is also possible that the ink contains a pH buffering agent, an anti-oxidation agent, an antibacterial agent, a viscosity adjusting agent, a conductive agent, an ultraviolet absorbing agent, or the like.

### <Treatment Liquid>

It is desirable in the present embodiment that the treatment liquid (aggregating treatment liquid) has effects of generating aggregation of the pigment and the polymer particles contained in the ink by producing a pH change in the ink when coming into contact with the ink.

Specific examples of the contents of the treatment liquid are: polyacrylic acid, acetic acid, glycolic acid, malonic acid, malic acid, maleic acid, ascorbic acid, succinic acid, glutaric acid, fumaric acid, citric acid, tartaric acid, lactic acid, sulfonic acid, orthophosphoric acid, pyrrolidone carboxylic acid, pyrone carboxylic acid, pyrrole carboxylic acid, furan carboxylic acid, pyridine carboxylic acid, cumaric acid, thiophene carboxylic acid, nicotinic acid, derivatives of these compounds, and salts of these.

A treatment liquid having added thereto a polyvalent metal salt or a polyallylamine is the preferred examples of the treatment liquid. The aforementioned compounds may be used individually or in combinations of two or more thereof.

From the standpoint of aggregation ability with the ink, the treatment liquid preferably has a pH of 1 to 6, more preferably a pH of 2 to 5, and even more preferably a pH of 3 to 5.

From the standpoint of preventing the nozzles of inkjet heads from being clogged by the dried treatment liquid, it is preferred that the treatment liquid include an organic solvent capable of dissolving water and other additives. A wetting agent and a penetrating agent are included in the organic solvent capable of dissolving water and other additives.

In order to improve fixing ability and abrasive resistance, the treatment liquid may further include a resin component. Any resin component may be employed, provided that the ejection ability from a head is not degraded when the treatment liquid is ejected by an inkjet system and also provided that the treatment liquid will have high stability in storage. Thus, water-soluble resins and resin emulsions can be freely used.

Apart from the foregoing, according to requirements, it is also possible that the ink contains a pH buffering agent, an anti-oxidation agent, an antibacterial agent, a viscosity adjusting agent, a conductive agent, an ultraviolet absorbing agent, or the like.

### Example of Application to Other Apparatus Compositions

The above-described embodiments relate to application to the inkjet recording apparatus for printing, but the scope of application of the present invention is not limited to these. For instance, it can also be applied widely to other inkjet recording apparatuses which obtain various shapes and patterns by using a liquid functional material, such as a wiring printing apparatus which prints a wiring pattern for an electronic circuit, or manufacturing apparatuses for various devices, a resist printing apparatus using resin liquid as a functional liquid for ejection, a color filter manufacturing apparatus or a fine structure forming apparatus which forms a fine structure by using a material deposition substance.

### APPENDIX

As has become evident from the detailed description of the embodiments given above, the present specification includes disclosure of various technical ideas described below.

It is preferable that a method of manufacturing an inkjet head comprises: an opening section forming step of forming, with respect to a SOI substrate having a first silicon layer, a second silicon layer and a first thermal oxide film between the first silicon layer and the second silicon layer, nozzle opening sections passing through the second silicon layer and the first thermal oxide film and reaching the first silicon layer; after the opening section forming step, a first silicon layer removing step of removing the first silicon layer; and after the first silicon layer removal step, a liquid-repellent film forming step of forming a liquid-repellent film on a surface of the first thermal oxide film that has been exposed in the first silicon layer removal step.

By using the first thermal oxide film, which has been buried in the SOI substrate, as an underlying layer of the liquid-repellent film of the nozzle surface, the wear resistance and the liquid resistance of the liquid-repellent film are improved. Furthermore, since the nozzle opening sections are protected until the first silicon layer is removed, then good operability is achieved and damage to the nozzle plate can be avoided.

Preferably, the opening section forming step includes: a second silicon layer etching step of etching the second silicon layer up to the first thermal oxide film; and after the second silicon layer etching step, a first thermal oxide film etching step of etching the first thermal oxide film up to the first silicon layer.

Etching is desirable as a method for forming the nozzle opening sections, and in the step of etching the second silicon layer, the first thermal oxide film acts as a stop layer, and in the step of etching the first thermal oxide film, the first silicon layer acts as a stop layer.

Preferably, anisotropic wet etching is carried out in the second silicon layer etching step.

Preferably, anisotropic dry etching is carried out in the first thermal oxide film etching step.

Preferably, the second silicon layer has a thickness in a range of 10 μm to 300 μm.

Preferably, the first thermal oxide film has a thickness in a range of 0.5 μm to 10 μm.

It is also preferable that the method further comprises: before the opening section forming step, a second thermal oxide film forming step of forming a second thermal oxide film on the second silicon layer, the second thermal oxide film serving as a flow channel protection film, wherein in the opening section forming step, the nozzle opening sections are formed to pass through the second thermal oxide film, the second silicon layer and the first thermal oxide film and reach the first silicon layer.

According to this mode, it is possible to form the flow channel protection film readily in a composition where the upper surface of the nozzle plate (the surface on the opposite side to the ejection surface) forms one portion of the flow channels with the flow channel structure body, which is to be bonded to the nozzle plate.

Preferably, the opening section forming step includes: a second thermal oxide film etching step of etching the second thermal oxide film up to the second silicon layer; after the second thermal oxide film etching step, a second silicon layer etching step of etching the second silicon layer up to the first thermal oxide film; and after the second silicon layer etching step, a first thermal oxide film etching step of etching the first thermal oxide film up to the first silicon layer.

Preferably, wet etching is carried out in the second thermal oxide film etching step.

Preferably, the first silicon layer removing step includes: a grinding step of removing a portion of the first silicon layer by grinding; and a first silicon layer etching step of etching the first silicon layer remaining after the grinding step, up to the first thermal oxide film.

According to this mode, it is possible to shorten the time required for the removal process compared to a case where the first silicon layer is removed by etching only. Furthermore, the present mode has high processing accuracy and little damage to the nozzle sections, compared to a case where the first silicon layer is removed by grinding only.

Preferably, after the grinding step, the first silicon layer has a thickness in a range of 0.1 μm to 300 μm.

It is also preferable that the method further comprises, after the opening section forming step and before the first silicon layer removing step, a third thermal oxide film forming step of forming a third thermal oxide film on nozzle inner surfaces of the nozzle opening sections, the third thermal oxide film serving as a flow channel protection film.

A desirable mode is one where the thermal oxide film for flow channel protection is also formed on the inner surfaces of the nozzles.

Preferably, the third thermal oxide film forming step includes: a thermal oxidation step of forming a thermal oxide film on the second silicon layer and the first silicon layer of the nozzle opening sections; and after the thermal oxidation step, an anisotropic dry etching step of removing the thermal oxide film on the first silicon layer formed in the thermal oxidation step.

Preferably, the third thermal oxide film has a thickness in a range of 0.5 μm to 1 μm.

It is also preferable that the method further comprises: before the first silicon layer removing step, a bonding step of bonding a flow channel structure body to the SOI substrate in which the nozzle opening sections have been formed in the opening section forming step, wherein the flow channel structure body in which a flow channel connecting to the nozzle opening sections is formed is manufactured separately from the SOI substrate in which the nozzle opening sections are formed.

According to this mode, it is possible to form a nozzle plate portion with good operability, without damaging the head main body, and the like.

Preferably, the flow channel structure body is provided with energy generating elements; and in the bonding step, the flow channel structure having the energy generating elements is bonded with the SOI substrate in which the nozzle opening sections are formed.

According to this mode, it is possible to form the nozzle plate portion with good operability, without damaging the energy generating devices, such as piezoelectric elements. Furthermore, it is also possible to carry out a driving test of the energy generation devices, such as the piezoelectric elements, in the independent unit of the flow channel structure body, before bonding the flow channel structure body with the SOI substrate in which the nozzle opening sections have been formed.

It is also preferable that an inkjet recording apparatus comprises the inkjet head manufactured by one of the above-described methods.

It should be understood that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A method of manufacturing an inkjet head, comprising:
an opening section forming step of forming, with respect to a SOI substrate having a first silicon layer, a second silicon layer and a first thermal oxide film between the first silicon layer and the second silicon layer, nozzle opening sections passing through the second silicon layer and the first thermal oxide film and reaching the first silicon layer;
after the opening section forming step, a first silicon layer removing step of removing the first silicon layer; and
after the first silicon layer removal step, a liquid-repellent film forming step of forming a liquid-repellent film on a surface of the first thermal oxide film that has been exposed in the first silicon layer removal step.

2. The method as defined in claim 1, wherein the opening section forming step includes:
a second silicon layer etching step of etching the second silicon layer up to the first thermal oxide film; and
after the second silicon layer etching step, a first thermal oxide film etching step of etching the first thermal oxide film up to the first silicon layer.

3. The method as defined in claim 2, wherein anisotropic wet etching is carried out in the second silicon layer etching step.

4. The method as defined in claim 2, wherein anisotropic dry etching is carried out in the first thermal oxide film etching step.

5. The method as defined in claim 1, wherein the second silicon layer has a thickness in a range of 10 μm to 300 μm.

6. The method as defined in claim 1, wherein the first thermal oxide film has a thickness in a range of 0.5 μm to 10 μm.

7. The method as defined in claim 1, further comprising:
before the opening section forming step, a second thermal oxide film forming step of forming a second thermal oxide film on the second silicon layer, the second thermal oxide film serving as a flow channel protection film,
wherein in the opening section forming step, the nozzle opening sections are formed to pass through the second thermal oxide film, the second silicon layer and the first thermal oxide film and reach the first silicon layer.

8. The method as defined in claim 7, wherein the opening section forming step includes:
a second thermal oxide film etching step of etching the second thermal oxide film up to the second silicon layer;
after the second thermal oxide film etching step, a second silicon layer etching step of etching the second silicon layer up to the first thermal oxide film; and
after the second silicon layer etching step, a first thermal oxide film etching step of etching the first thermal oxide film up to the first silicon layer.

9. The method as defined in claim 8, wherein wet etching is carried out in the second thermal oxide film etching step.

10. The method as defined in claim 8, wherein anisotropic wet etching is carried out in the second silicon layer etching step.

11. The method as defined in claim 8, wherein anisotropic dry etching is carried out in the first thermal oxide film etching step.

12. The method as defined in claim 7, wherein the second thermal oxide film has a thickness in a range of 0.5 μm to 10 μm.

13. The method as defined in claim 1, wherein the first silicon layer removing step includes:
a grinding step of removing a portion of the first silicon layer by grinding; and
a first silicon layer etching step of etching the first silicon layer remaining after the grinding step, up to the first thermal oxide film.

14. The method as defined in claim 13, wherein after the grinding step, the first silicon layer has a thickness in a range of 0.1 μm to 300 μm.

15. The method as defined in claim 1, further comprising, after the opening section forming step and before the first silicon layer removing step, a third thermal oxide film forming step of forming a third thermal oxide film on nozzle inner surfaces of the nozzle opening sections, the third thermal oxide film serving as a flow channel protection film.

16. The method as defined in claim 15, wherein the third thermal oxide film forming step includes:
a thermal oxidation step of forming a thermal oxide film on the second silicon layer and the first silicon layer of the nozzle opening sections; and
after the thermal oxidation step, an anisotropic dry etching step of removing the thermal oxide film on the first silicon layer formed in the thermal oxidation step.

17. The method as defined in claim 15, wherein the third thermal oxide film has a thickness in a range of 0.5 μm to 1 μm.

18. The method as defined in claim 1, further comprising:
before the first silicon layer removing step, a bonding step of bonding a flow channel structure body to the SOI substrate in which the nozzle opening sections have been formed in the opening section forming step,
wherein the flow channel structure body in which a flow channel connecting to the nozzle opening sections is formed is manufactured separately from the SOI substrate in which the nozzle opening sections are formed.

19. The method as defined in claim 18, wherein:
the flow channel structure body is provided with energy generating elements; and
in the bonding step, the flow channel structure having the energy generating elements is bonded with the SOI substrate in which the nozzle opening sections are formed.

20. An inkjet recording apparatus comprising the inkjet head manufactured by the method as defined in claim 1.
